(19) United States
(12) Patent Application Publication
(10) Pub. No.: US 2003/0162378 A1
(43) Pub. Date: Aug. 28, 2003

(54) Bonding method and bonding apparatus

(75) Inventor: Kunimitsu Mikami, Sakata-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/320,535

(22) Filed: Dec. 17, 2002

(30) Foreign Application Priority Data
Dec. 28, 2001 (JP) 2001-400234

(51) Int. Cl. H01L 21/44

(52) U.S. Cl. 438/612; 438/617

(57) ABSTRACT

A tip of a wire is formed in a shape of a ball, the wire being inserted into and fed out of a first tool. The tip is bonded to a first electrode by using the first tool. The wire is drawn from the first tool and a part of the wire is bonded to a second electrode by using the first tool. The wire is held by a second tool disposed above the first tool, and cut in a state to allow the part of the wire to remain on the second electrode. The wire is fed out of the first tool by positioning the first and second tools relatively closer to each other while holding the wire by the second tool.

Japanese Patent Application No. 2001-400234 filed on Dec. 28, 2001, is hereby incorporated by reference in its entirety.

### BACKGROUND OF THE INVENTION

The present invention relates to a bonding method and a bonding apparatus.

In the manufacture of semiconductor devices, a wire bonding step in which pads of a semiconductor chip are electrically connected with leads is performed. In the wire bonding step, the tip of a wire fed out of a capillary is formed in the shape of a ball by using a torch, and the ball is bonded to the pad. The wire is then fed and bonded to the lead.

The wire is fed out of the capillary to a predetermined length and then cut. In more detail, the wire is fed out of the capillary to a predetermined length by opening a clamper which holds the wire and raising the clamper and the capillary at the same time while allowing the wire to be connected with the lead. The wire is then cut.

However, this step may cause the wire to rub against the capillary when raising the clamper and the capillary, whereby the wire may be cut before the wire is fed to a predetermined length. This may cause the distance between the torch and the tip of the wire to be changed in each bonding step, whereby bonding quality may not be maintained uniformly due to unevenness of the size of the ball at the tip of the wire. Such a problem may occur in a step of forming a bump by using a ball bump method, for example.

### BRIEF SUMMARY OF THE INVENTION

A bonding method according to an aspect of the present invention comprises steps of:

forming a tip of a wire in a shape of a ball, the wire being inserted into and fed out of a first tool;

bonding the tip to a first electrode by using the first tool;

drawing the wire from the first tool and bonding a part of the wire to a second electrode by using the first tool;

holding the wire by a second tool disposed above the first tool, and cutting the wire in a state to allow the part of the wire to remain on the second electrode; and

feeding the wire out of the first tool by positioning the first and second tools relatively closer to each other while holding the wire by the second tool.

A bonding method according to another aspect of the present invention comprises steps of:

forming a tip of a wire in a shape of a ball, the wire being inserted into and fed out of a first tool;

bonding the tip to an electrode by using the first tool;

holding the wire by a second tool disposed above the first tool, and cutting the wire in a state to allow the tip to remain on the electrode; and

feeding the wire out of the first tool by positioning the first and second tools relatively closer to each other while holding the wire by the second tool.

A bonding apparatus according to a further aspect of the present invention comprises:

a first tool into which a wire is inserted; and

a second tool disposed above the first tool, the second tool being capable of holding the wire and movable relative to the first tool,

wherein the wire is fed out of the first tool by positioning the first and second tools relatively closer to each other while holding the wire by the second tool.

### BRIEF DESCRIPTION OF THE SEVERAL VIEWS OF THE DRAWING

FIGS. 1A to 1C show a manufacturing method and a manufacturing apparatus for a semiconductor device according to a first embodiment of the present invention;

FIGS. 2A and 2B show the manufacturing method and the manufacturing apparatus for a semiconductor device according to the first embodiment of the present invention;

FIG. 3 shows a semiconductor device manufactured according to the first embodiment of the present invention;

FIGS. 4A and 4B show a manufacturing method and a manufacturing apparatus for a semiconductor device according to a second embodiment of the present invention;

FIGS. 5A and 5B show the manufacturing method and the manufacturing apparatus for a semiconductor device according to the second embodiment of the present invention;

FIG. 6 shows a semiconductor device manufactured according to the second embodiment of the present invention;

FIG. 7 shows electronic equipment according to an embodiment of the present invention; and

FIG. 8 shows electronic equipment according to an embodiment of the present invention.

### DETAILED DESCRIPTION OF THE EMBODIMENT

Embodiments of the present invention may enable bonding capable of increasing reliability of a semiconductor device and maintaining a uniform quality of the semiconductor device.

(1) A bonding method according to one embodiment of the present invention comprises steps of:

forming a tip of a wire in a shape of a ball, the wire being inserted into and fed out of a first tool;

bonding the tip to a first electrode by using the first tool;

drawing the wire from the first tool and bonding a part of the wire to a second electrode by using the first tool;

holding the wire by a second tool disposed above the first tool, and cutting the wire in a state to allow the part of the wire to remain on the second electrode; and

feeding the wire out of the first tool by positioning the first and second tools relatively closer to each other while holding the wire by the second tool.

According to this embodiment, the wire is fed out of the first tool by moving the first and second tools relatively after cutting the wire. Therefore, the wire can be reliably fed out of the first tool with a uniform length even if the wire rubs against the first tool. Specifically, the tip of the wire can be disposed at a uniform position every time the wire is fed in the step of forming the tip in the shape of a ball. Therefore, reliability of the product can be increased and the quality of the product can be maintained uniformly by making the size of the ball at the tip of the wire uniform.

(2) In this bonding method, a plurality of the first electrodes and a plurality of the second electrodes may be electrically connected through the wire by repeating each of the steps.

(3) In this bonding method, the first electrode may be a pad of a semiconductor chip, and

the second electrode may be an inner lead of a lead frame.

(4) In this bonding method, the first electrode may be an inner lead of a lead frame, and

the second electrode may be a pad of a semiconductor chip.

(5) A bonding method according to another embodiment of the present invention comprises steps of:

forming a tip of a wire in a shape of a ball, the wire being inserted into and fed out of a first tool;

bonding the tip to an electrode by using the first tool;

holding the wire by a second tool disposed above the first tool, and cutting the wire in a state to allow the tip to remain on the electrode; and

feeding the wire out of the first tool by positioning the first and second tools relatively closer to each other while holding the wire by the second tool.

According to this embodiment, the wire is fed out of the first tool by moving the first and second tools relatively after cutting the wire. Therefore, the wire can be reliably fed out of the first tool with a uniform length even if the wire rubs against the first tool. Specifically, the tip of the wire can be disposed at a uniform position every time the wire is fed in the step of forming the tip in the shape of a ball. Therefore, reliability of the product can be increased and the quality of the product can be maintained uniformly by making the size of the ball at the tip of the wire uniform.

(6) In this bonding method, a bump may be formed by the tip of the wire remained on the electrode.

(7) In this bonding method, the electrode may be a pad of a semiconductor wafer.

(8) In this bonding method, the wire may be cut near an end of the first tool without feeding the wire out of the first tool, in the step of cutting the wire.

This enables the wire to be cut at a uniform position, whereby the wire can be easily fed out of the first tool with a uniform length.

(9) In this bonding method, the wire may be cut by raising the first and second tools at the same time, in the step of cutting the wire.

This enables the wire to be easily cut.

(10) In this bonding method, the wire maybe fed by lowering the second tool in the step of feeding the wire.

This enables the wire to be easily fed out of the first tool.

(11) A bonding apparatus according to a further embodiment of the present invention comprises:

a first tool into which a wire is inserted; and

a second tool disposed above the first tool, the second tool being capable of holding the wire and movable relative to the first tool,

wherein the wire is fed out of the first tool by positioning the first and second tools relatively closer to each other while holding the wire by the second tool.

According to this embodiment, the wire can be fed out of the first tool by moving the first and second tools relatively. Therefore, the wire can be reliably fed out of the first tool with a uniform length even if the wire rubs against the first tool. This enables a tip of the wire to be disposed at a uniform position every time the wire is fed in the step of forming the tip in the shape of a ball, for example. Therefore, reliability of the product can be increased and the quality of the product can be maintained uniformly by making the size of the ball at the tip of the wire uniform.

(12) In this bonding apparatus,

a tip of the wire may be formed in a shape of a ball, and may be bonded to a first electrode by the first tool,

the wire may be drawn from the first tool, and a part of the wire may be bonded to a second electrode by the first tool, and

the wire may be held by the second tool and cut in a state to allow the part of the wire to remain on the second electrode.

(13) In this bonding apparatus, a plurality of the first electrodes and a plurality of the second electrodes may be electrically connected through the wire.

(14) In this bonding apparatus,

a tip of the wire may be formed in a shape of a ball, and may be bonded to an electrode by the first tool, and

the wire may be held by the second tool and cut in a state to allow the tip of the wire to remain on the electrode.

(15) In this bonding apparatus, a bump may be formed by the tip of the wire remained on the electrode.

(16) In this bonding apparatus, the wire may be cut near an end of the first tool by the second tool without feeding the wire out of the first tool.

This enables the wire to be cut at a uniform position, whereby the wire can be easily fed out of the first tool with a uniform length.

(17) In this bonding apparatus, the wire may be cut by raising the first and second tools at the same time.

This enables the wire to be easily cut.

(18) In this bonding apparatus, the wire may be fed by lowering the second tool.

This enables the wire to be easily fed out of the first tool.

The embodiments of the present invention are described below with reference to the drawings. The present invention includes a manufacturing method and a manufacturing apparatus for a semiconductor device illustrated in the following embodiments. However, the present invention is not limited to the embodiments described below. The present invention may be applied to a manufacturing method and a manufacturing apparatus for other electronic devices.

First Embodiment

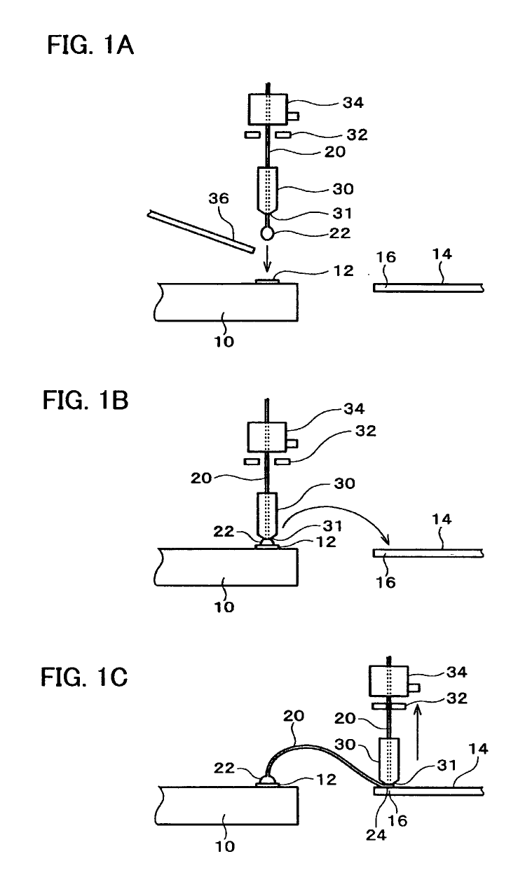

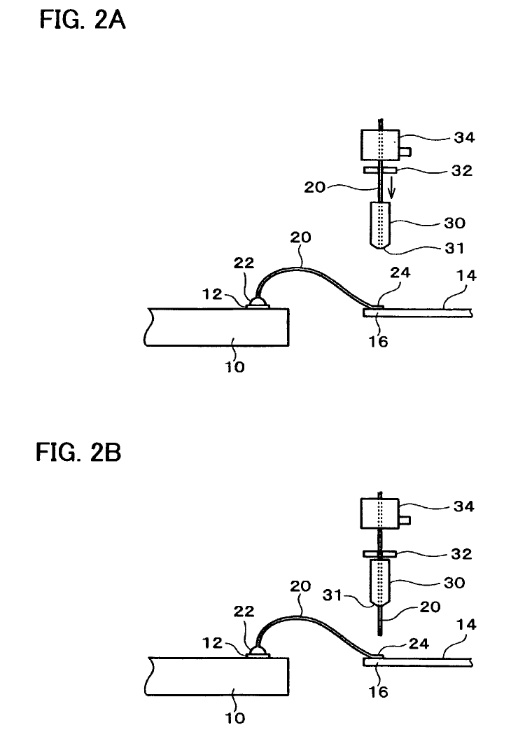

FIGS. 1A to 2B show a manufacturing method and a manufacturing apparatus (or a wire bonding method and a wire bonding apparatus) for a semiconductor device according to a first embodiment of the present invention.

As shown in FIG. 1A, a semiconductor chip 10 on which a plurality of pads 12 are formed and a plurality of leads 14, are provided.

The semiconductor chip 10 has a surface (active surface) on which an integrated circuit is formed. The integrated circuit is formed on the surface having the largest area of the semiconductor chip 10 in the shape of a rectangular parallelepiped. The pads 12 are generally formed on the surface of the semiconductor chip 10 on which the integrated circuit is formed. The pads 12 are generally formed of an aluminum-based or copper-based metal thinly and flatly on the semiconductor chip 10. A passivation film (not shown) may be formed on the semiconductor chip 10 so as to avoid the pads 12. The passivation film may be formed of SiO₂, SiN, a polyimide resin, or the like.

As shown in FIG. 1A, the leads 14 may have a free end without being supported by other members. The leads 14 are disposed outside the semiconductor chip 10. The leads 14 may be a part of a lead frame (not shown). In more detail, each of the leads 14 is formed of an inner lead 16 and an outer lead (not shown) connected with each other. The leads 14 are disposed so that the inner leads 16 face the semiconductor chip 10.

The leads 14 may be supported by a substrate (not shown). Specifically, the leads 14 may be interconnecting lines formed on a substrate. The interconnecting lines have electrically contacting sections (lands, for example) with the semiconductor chip 10. The semiconductor chip 10 is mounted on the surface of the substrate on which the interconnecting lines are formed. The electrically contacting sections are disposed outside the semiconductor chip 10.

In this embodiment, the semiconductor chip 10 and the leads 14 are electrically connected through wires 20. In more detail, the pads 12 of the semiconductor chip 10 and the inner leads 16 of the leads 14 are wire bonded by using a manufacturing apparatus shown in FIG. 1A.

The manufacturing apparatus according to this embodiment includes first and second tools 30 and 32. In this embodiment, the first tool 30 is a capillary and the second tool 32 is a clamper. The first and second tools 30 and 32 can be moved three-dimensionally. In more detail, the first and second tools 30 and 32 can be moved along XY axes (an axis in the horizontal direction in FIG. 1A and an axis in the direction perpendicular to the surface of FIG. 1A) which intersect at right angles, parallelly to a bonding surface (surface on which the pads 12 are formed) of the semiconductor chip 10. The first and second tools 30 and 32 can also be moved along a Z axis (axis in the vertical direction in FIG. 1A) perpendicular to the bonding surface. The first and second tools 30 and 32 may be moved integrally together (while maintaining the distance between the first and second tools 30 and 32 uniform) along the XYZ axes.

The first tool 30 has a guide section into which the wire 20 can be inserted in the axial direction. In the example shown in FIG. 1A, the guide section is a hole. The hole in the first tool 30 is formed to have a greater diameter than the diameter of the wire 20. The wire 20 can be allowed to pass through the inside of the hole. The first tool 30 has a pressing section 31 which presses a tip 22 of the wire 20. In the example shown in FIG. 1A, the pressing section 31 is an open end of the hole into which the wire 20 is inserted. The first tool 30 is supported on a main body (wire bonder; not shown) of the manufacturing apparatus by a support such as an ultrasonic horn (not shown).

The second tool 32 has a function of holding the wire 20. In more detail, the second tool 32 secures the wire 20 so that the wire 20 is not moved in the Z axis direction perpendicular to the bonding surface of the semiconductor chip 10. In this embodiment, the second tool 32 closes from each side of the wire 20 to sandwich the wire 20. The second tool 32 is disposed above the first tool 30, specifically, above the side of the first tool 30 opposite to the pressing section 31. The second tool 32 can be moved relative to the first tool 30 along the Z axis perpendicular to the bonding surface of the semiconductor chip 10. Specifically, only the first tool 30 may be moved along the Z axis or only the second tool 32 may be moved along the Z axis. The first and second tools 30 and 32 may be moved along the Z axis in different directions at different speeds. In this case, the second tool 32 can be moved in either a closed state or an open state.

The manufacturing apparatus according to this embodiment includes a third tool 34 which applies tension (air tension, for example) to the wire 20 in a direction opposite to the semiconductor chip 10. The third tool 34 is disposed above the second tool 32, specifically, above the side of the second tool 32 opposite to the first tool 30. The third tool 34 may have a function of applying tension to the wire 20 using air, as shown in FIG. 1A. This enables bonding load to be easily controlled and the wire 20 to be easily looped into a predetermined shape. The third tool 34 may apply tension to the wire 20 by winding the wire 20. The third tool 34 may be able to move along the XYZ axes together with the first and second tool 30 and 32. The third tool 34 may be able to move along only the XY axes.

The manufacturing apparatus according to this embodiment includes a torch 36. The torch 36 causes the tip 22 of the wire 20 disposed outside the first tool 30, specifically, below the pressing section 31, to be formed in the shape of a ball. The torch 36 may cause the tip 22 to be melted by applying discharge energy or thermal energy such as gas flame and formed in the shape of ball. There are no specific limitations to the shape of the ball-shaped tip 22 insofar as the tip 22 is in the shape of a lump.

The manufacturing apparatus for a semiconductor device according to this embodiment has the above-described configuration. A manufacturing method for a semiconductor device is described below. The items described above may be applied to specific items in the method described below.

As shown in FIG. 1A, the first tool 30 is disposed above the surface of the semiconductor chip 10 on which the pads 12 are formed. The wire 20 is inserted into the first tool 30. The wire 20 is formed of a conductive material such as gold. The tip 22 of the wire 20 is disposed outside the first tool 30. The second and third tools 32 and 34 are disposed above the first tool 30. The third tool 34 applies tension to the wire 20. In this embodiment, the third tool 34 is moved together with the first and second tools 30 and 32 along the XY axes on a plane parallel to the bonding surface of the semiconductor chip 10.

The tip 22 of the wire 20 is formed in the shape of a ball. As shown in FIG. 1A, the torch 36 is moved closer to the tip 22 of the wire 20. In the case where the torch 36 is an electric torch, the tip 22 is formed in the shape of a ball by melting the tip 22 by causing high voltage discharge. In this case, it is desirable that the distance between the tip of the torch 36 and the tip 22 of the wire 20 be uniform every time in order to make the size of the ball uniform. According to this embodiment, the tip 22 of the wire 20 can be disposed at a uniform position when forming the tip 22 of the wire 20 in the shape of a ball as described later. In this step, the second tool 32 may release the wire 20 in an open state as shown in FIG. 1A, or hold the wire 20 in a closed state.

As shown in FIG. 1B, the tip 22 of the wire 20 is disposed above one of the pads 12. The tip 22 is pressed against the pad 12 by the pressing section 31 by lowering the first tool 30. Ultrasonic waves, heat, or the like are applied while pressing the tip 22 against the pad 12 at a uniform pressure. In the case where the second tool 32 is in an open state as shown in FIG. 1B, the first and second tools 30 and 32 maybe integrally lowered together. In the case where the second tool 32 is in a closed state, the first tool 30 is moved to a position lower than the second tool 32 so that the pressing section 31 comes in contact with the tip 22 of the wire 20.

In this embodiment, the wire 20 is bonded to the pad 12 (first electrode) of the semiconductor chip 10 and then bonded to the inner lead 16 (second electrode) of the lead 14, as shown in FIG. 1B.

As shown in FIGS. 1B and 1C, the wire 20 is moved toward the inner lead 16 in a state in which the tip 22 is bonded to the pad 12 by moving the first tool 30 from the pad 12 to the inner lead 16. When moving the wire 20, the second tool 32 releases the wire 20 in an open state. The first to third tools 30, 32, and 34 may be moved integrally together. The wire 20 may loop three-dimensionally. Apart 24 of the wire 20 is bonded to the inner lead 16. In more detail, the part 24 of the wire 20 is pressed against the inner lead 16 by the pressing section 31 by lowering the first tool 30 toward the inner lead 16. Ultrasonic waves, heat, or the like may be applied while pressing the part 24 of the wire 20 against the inner lead 16 at a uniform pressure.

As shown in FIGS. 1C to 2B, a step of cutting the wire 20 and a step of feeding the wire 20 out of the first tool 30 are performed.

As shown in FIGS. 1C and 2A, the second tool 32 is raised after bonding in a state in which the wire 20 is held by closing the second tool 32. The wire 20 is cut while allowing the part 24 bonded to the inner lead 16 to remain. In this case, the wire 20 may be cut near the pressing section 31 of the first tool 30 without feeding the wire 20 from the first tool 30. This enables the wire 20 to be cut at a uniform position. Therefore, the wire 20 can be easily fed out of the first tool 30 with a uniform length.

As shown in FIG. 2A, the first and second tools 30 and 32 may be raised at the same time in the step of cutting the wire 20. In this case, the first and second tools 30 and 32 may be raised integrally together (while maintaining the distance between the first and second tools 30 and 32 uniform). This allows the first and second tools 30 and 32 to be integrally controlled together, whereby the wire 20 can be cut by a simple step.

As shown in FIGS. 2A and 2B, after raising the first and second tools 30 and 32, the first and second tools 30 and 32 are positioned relatively closer to each other in a closed state (in a state in which the wire 20 is held by the second tool 32). In this case, the second tool 32 may be lowered as shown in FIG. 2A. The first tool 30 may be raised, or the first tool 30 and the second tool 32 may be raised or lowered at the same time. As shown in FIG. 2B, the wire 20 is fed out of the first tool 30. In the case where the wire 20 is cut without feeding the wire 20 from the first tool 30, the wire 20 can be fed out of the first tool 30 to a length equal to the distance at which the second tool 32 is lowered, for example. Therefore, the length of the wire 20 fed out of the first tool 30 can be set precisely.

The tip 22 of the wire 20 can be fed out of the first tool 30 in this manner, as shown in FIG. 2B. The distance between the first and second tools 30 and 32 is smaller than the distance between the tools when bonding the part 24 of the wire 20 to the inner lead 16.

In the case where it is necessary to wire bond a plurality of pairs of the pad 12 and the lead 14, the above-described steps are repeated for a plurality of the pads 12 and the leads 14. Specifically, the tip of the wire 20 fed out of the first tool 30 shown in FIG. 2B is formed in the shape of a ball as shown in FIG. 1A, and bonded to another pad 12. In this case, it is desirable to separate the first and second tools 30 and 32 by a uniform distance when starting wire bonding or in the middle of wire bonding in order to feed the wire 20 from the first tool 30 in the next wire bonding step.

According to this embodiment, the wire 20 is fed out of the first tool 30 by moving the first and second tools 30 and 32 relatively, after cutting the wire 20. Therefore, the wire 20 can be reliably fed out of the first tool 30 with a uniform length, even if the wire 20 rubs against the first tool 30. Specifically, the tip 22 of the wire 20 can be disposed at a uniform position in the step of forming the tip 22 in the shape of a ball. Therefore, a manufacturing method and a manufacturing apparatus capable of increasing reliability of the product and maintaining the quality of the product uniform can be provided by making the size of the ball at the tip 22 of the wire 20 uniform.

As a modification of this embodiment, the wire 20 may be bonded to the inner lead 16 (first electrode) of the lead 14, and then bonded to the pad 12 (second electrode) of the semiconductor chip 10. Specifically, the tip 22 of the wire 20 formed in the shape of a ball may be bonded to the inner lead 16. In this case, it is desirable to form a bump on the pad 12 in advance and second bond a part of the wire 20 through the bump. This enables the wire 20 and the pad 12 to be electrically connected without causing a damage to the thin pad 12. The above-described effects can also be achieved in this modification.

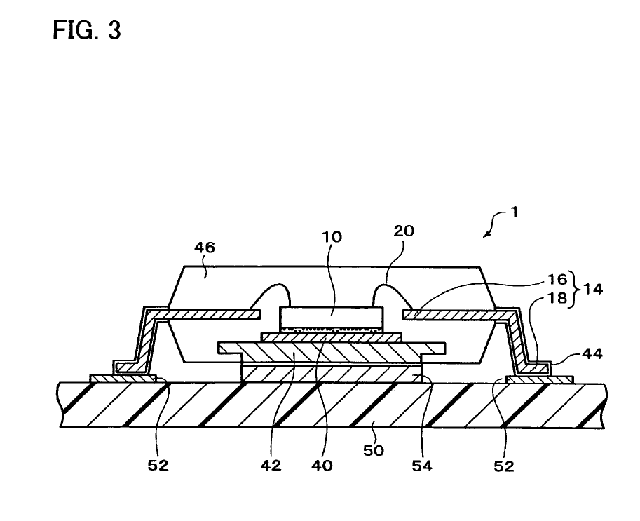

FIG. 3 shows an example of a semiconductor device manufactured by the above-described method. In FIG. 3, a semiconductor device is mounted on a circuit board.

A semiconductor device 1 includes the semiconductor chip 10, the leads 14, the wires 20 which electrically connect the semiconductor chip 10 with the leads 14, and a sealing section 46 which seals at least the semiconductor chip 10. In the example shown in FIG. 3, the semiconductor chip 10 is mounted face up on a die pad 40. A heat sink 42 is provided to the die pad 40 on the side opposite to the semiconductor chip 10. The heat sink 42 is partly exposed from the sealing section 46, whereby heat radiation properties of the semiconductor chip 10 can be improved. Each of the leads 14 includes the inner lead 16 and the outer lead 18. The outer leads 18 project outside the sealing section 46 and are bent in a predetermined shape (gull-wing shape in FIG. 3). It is desirable that a metal film 44 such as a soldering material be provided to the outer leads 18 by using a plating method or the like.

In FIG. 3, the semiconductor device 1 is mounted on a circuit board 50. As the circuit board 50, an organic substrate such as a glass epoxy substrate is generally used. An interconnecting pattern 52 is formed of copper or the like on the circuit board 50 so that a desired circuit is formed. The interconnecting pattern 52 is bonded to the outer leads 18 of the semiconductor device 1. A radiation member 54 is provided to the circuit board 50. The radiation member 54 is bonded to the exposed surface of the heat sink 42 of the semiconductor device 1. This enables heat generated in the semiconductor chip 10 to be radiated from the radiation member 54 through the heat sink 42.

Second Embodiment

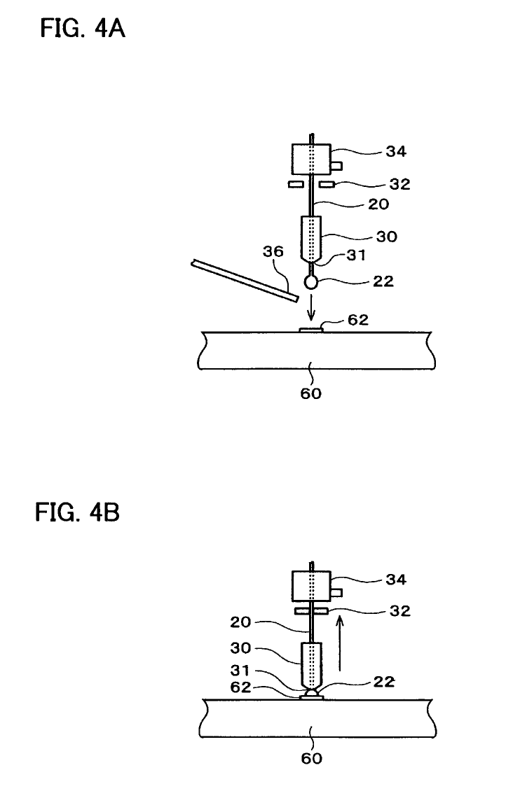

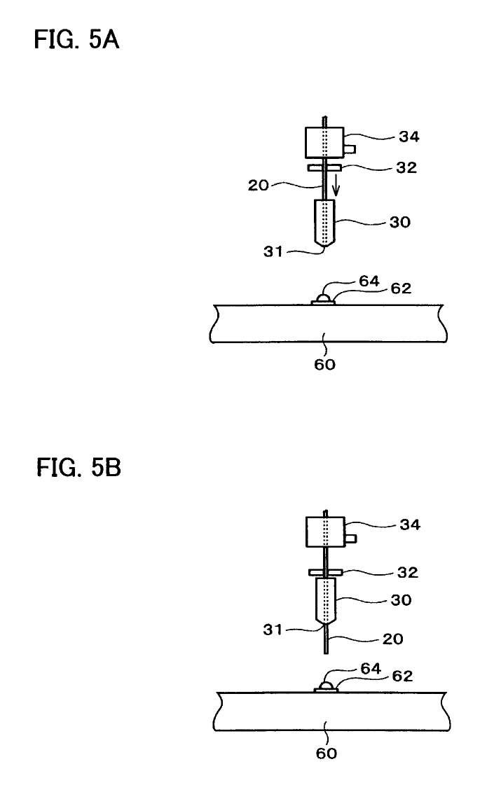

FIGS. 4A to 5B show a manufacturing method and a manufacturing apparatus (or a bump formation method and a bump formation apparatus) for a semiconductor device according to a second embodiment of the present invention. In this embodiment, the manufacturing apparatus for a semiconductor device described in the above embodiment may be utilized. Any of the content described in the above embodiment may be selectively applied to this embodiment.

As shown in FIG. 4A, a semiconductor wafer 60 is provided. The semiconductor wafer 60 has a surface (active surface) on which an integrated circuit is formed. A plurality of pads 62 are formed on the surface of the semiconductor wafer 60 on which the integrated circuit is formed. A passivation film (not shown) may be formed on the semiconductor wafer 60 so as to avoid the pads 62. In this embodiment, a bump formation process is performed in a state of a wafer by batch processing. As a modification, the bump formation process may be performed in a state of a chip.

As shown in FIG. 4A, the first tool 30 is disposed above the surface of the semiconductor wafer 60 on which the pads 62 are formed. The wire 20 is inserted into the first tool 30. The tip 22 of the wire 20 is disposed outside the first tool 30. The second and third tools 32 and 34 are disposed above the first tool 30.

Any of the details described in the first embodiment may be selectively applied to the first to third tools 30, 32, and 34 (including movement).

As shown in FIG. 4A, the tip 22 of the wire 20 is formed in the shape of a ball. The above-described details may be applied to a method of forming the tip 22 in the shape of a ball.

As shown in FIG. 4B, the tip 22 of the wire 20 is disposed above one of the pads 62. The tip 22 is pressed against the pad 62 by the pressing section 31 by lowering the first tool 30. In this embodiment, bumps 64 (see FIG. 5A) are formed on each of a plurality of the pads 62 (electrodes) of the semiconductor wafer 60.

As shown in FIGS. 4B to 5B, the step of cutting the wire 20 and the step of feeding the wire 20 from the first tool 30 are performed.

As shown in FIGS. 4B and 5A, the second tool 32 is raised after bonding in a state in which the wire 20 is held by closing the second tool 32. The wire 20 is cut while allowing the tip 22 bonded to the pad 62 to remain. In this case, the wire 20 may be cut near the pressing section 31 of the first tool 30 without feeding the wire 20 from the first tool 30, as shown in FIG. 5A. Specifically, the wire 20 is cut at the neck led from the tip 22. This enables the wire 20 to be cut at a uniform position. Therefore, the wire 20 can be easily fed out of the first tool 30 with a uniform length.

As shown in FIG. 5A, the first and second tools 30 and 32 may be raised at the same time in the step of cutting the wire 20. In this case, the first and second tools 30 and 32 may be raised integrally together (while maintaining the distance between the first and second tools 30 and 32 uniform). This allows the first and second tools 30 and 32 to be integrally controlled together, whereby the wire 20 can be cut by a simple step.

As shown in FIGS. 5A and 5B, after raising the first and second tools 30 and 32, the second tool 32 is moved relatively closer to the first tool 30 in a closed state (in a state in which the wire 20 is held by the second tool 32). In this case, the second tool 32 maybe lowered as shown in FIG. 5A. The first tool 30 may be raised, or the first tool 30 may be raised and the second tool 32 may be lowered at the same time. AS shown in FIG. 5B, the wire 20 is fed out of the first tool 30. In the case where the wire 20 is cut without feeding the wire 20 from the first tool 30, the wire 20 can be fed out of the first tool 30 to a length equal to the distance at which the second tool 32 is lowered, for example. Therefore, the length of the wire 20 fed out of the first tool 30 can be set precisely.

The tip of the wire 20 can be fed out of the first tool 30 in this manner, as shown in FIG. 5B. The distance between the first and second tools 30 and 32 is smaller than the distance between the tools when bonding the part 24 of the wire 20 to the inner lead 16.

In the case where it is necessary to form the bumps on a plurality of the pads 62, the above steps are repeated for each pad 62. In this case, it is desirable to separate the first and second tools 30 and 32 by a uniform distance when starting the bump formation step or in the middle of the bump formation step so that the wire 20 can be fed out of the first tool 30 in the next bump formation step.

If necessary, a plurality of the bumps 64 formed on the semiconductor wafer 60 may be leveled. This decreases unevenness of the height of the bumps 64. The semiconductor wafer 60 is divided into a plurality of individual semiconductor chips 66 by performing a predetermined step such as a dicing step.

In this embodiment, the effects described in the first embodiment can also be achieved.

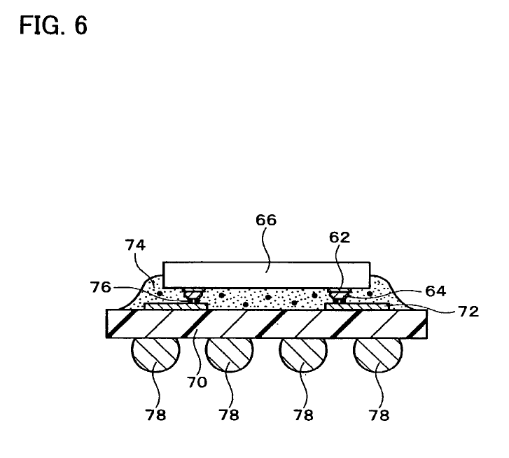

FIG. 6 shows an example of a semiconductor device manufactured by the above-described method. This semiconductor device includes the semiconductor chip 66, and a substrate 70 on which the semiconductor chip 66 is mounted face down. A plurality of the pads 62 are formed on the semiconductor chip 66. The bumps 64 are formed on the pads 62. An interconnecting pattern 72 is formed on the substrate 70. The semiconductor chip 66 may be mounted on the substrate 70 through an adhesive material. In the case where an anisotropic conductive material 74 is used as the adhesive material, the semiconductor chip 66 and the interconnecting pattern 72 can be electrically connected by allowing conductive particles 76 in a binder to be interposed between the bumps 64 and the interconnecting pattern 72.

A plurality of external terminals (solder balls, for example) 78 are provided to the substrate 70. The external terminals 78 are electrically connected with the interconnecting pattern 72. For example, the external terminals 78 may be provided to the substrate 70 on the surface opposite to the surface on which the semiconductor chip 66 is mounted through through-holes (not shown) formed in the substrate 70.

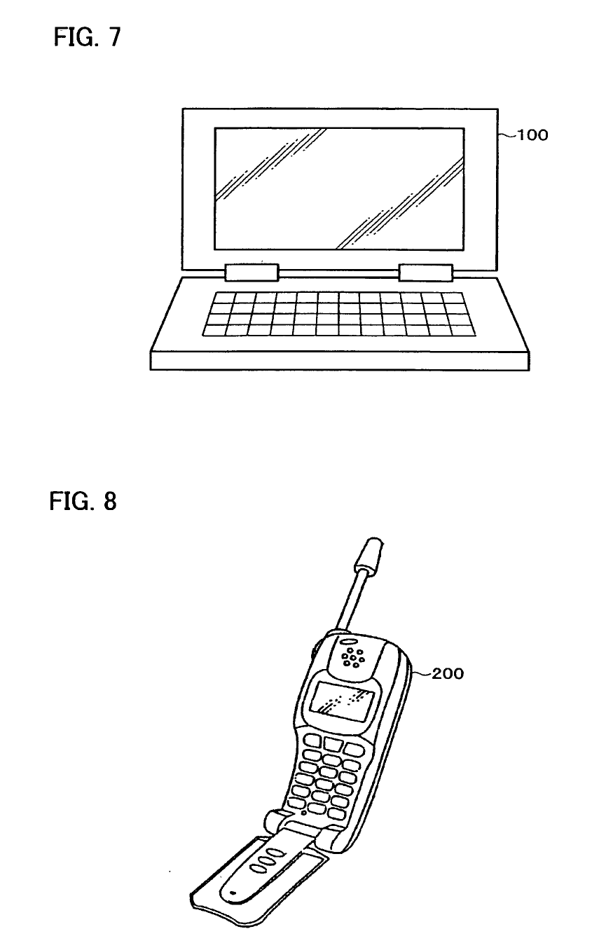

FIGS. 7 and 8 respectively show a notebook-type personal computer 100 and a portable telephone 200 as examples of electronic equipment including the semiconductor device to which the present invention is applied.

The present invention is not limited to the above-described embodiments and various modifications and variations are possible. For example, the present invention includes configurations essentially the same as the configurations described in the embodiments (for example, configurations having the same function, method, and results, or configurations having the same object and results). The present invention includes configurations in which any unessential part of the configuration described in the embodiments is replaced. The present invention includes configurations having the same effects or achieving the same object as the configurations described in the embodiments. The present invention includes configurations in which conventional technology is added to the configurations described in the embodiments.

What is claimed is:

1. A bonding method comprising steps of:
forming a tip of a wire in a shape of a ball, the wire being inserted into and fed out of a first tool;
bonding the tip to a first electrode by using the first tool;
drawing the wire from the first tool and bonding a part of the wire to a second electrode by using the first tool;
holding the wire by a second tool disposed above the first tool, and cutting the wire in a state to allow the part of the wire to remain on the second electrode; and
feeding the wire out of the first tool by positioning the first and second tools relatively closer to each other while holding the wire by the second tool.

2. The bonding method as defined by claim 1,
wherein a plurality of the first electrodes and a plurality of the second electrodes are electrically connected through the wire by repeating each of the steps.

3. The bonding method as defined by claim 1,
wherein the first electrode is a pad of a semiconductor chip, and
wherein the second electrode is an inner lead of a lead frame.

4. The bonding method as defined by claim 1,
wherein the first electrode is an inner lead of a lead frame, and
wherein the second electrode is a pad of a semiconductor chip.

5. The bonding method as defined by claim 1,
wherein the wire is cut near an end of the first tool without feeding the wire out of the first tool, in the step of cutting the wire.

6. The bonding method as defined by claim 1,
wherein the wire is cut by raising the first and second tools at the same time, in the step of cutting the wire.

7. The bonding method as defined by claim 1,
wherein the wire is fed by lowering the second tool in the step of feeding the wire.

8. A bonding method comprising steps of:
forming a tip of a wire in a shape of a ball, the wire being inserted into and fed out of a first tool;
bonding the tip to an electrode by using the first tool;
holding the wire by a second tool disposed above the first tool, and cutting the wire in a state to allow the tip to remain on the electrode; and
feeding the wire out of the first tool by positioning the first and second tools relatively closer to each other while holding the wire by the second tool.

9. The bonding method as defined by claim 8,
wherein a bump is formed by the tip of the wire remained on the electrode.

10. The bonding method as defined by claim 8,
wherein the electrode is a pad of a semiconductor wafer.

11. The bonding method as defined by claim 8,
wherein the wire is cut near an end of the first tool without feeding the wire out of the first tool, in the step of cutting the wire.

12. The bonding method as defined by claim 8,
wherein the wire is cut by raising the first and second tools at the same time, in the step of cutting the wire.

13. The bonding method as defined by claim 8,
wherein the wire is fed by lowering the second tool in the step of feeding the wire.

14. A bonding apparatus comprising:
a first tool into which a wire is inserted; and
a second tool disposed above the first tool, the second tool being capable of holding the wire and movable relative to the first tool,
wherein the wire is fed out of the first tool by positioning the first and second tools relatively closer to each other while holding the wire by the second tool.

15. The bonding apparatus as defined by claim 14,
wherein a tip of the wire is formed in a shape of a ball, and is bonded to a first electrode by the first tool,
wherein the wire is drawn from the first tool, and a part of the wire is bonded to a second electrode by the first tool, and
wherein the wire is held by the second tool and cut in a state to allow the part of the wire to remain on the second electrode.

16. The bonding apparatus as defined by claim 14,
wherein a plurality of the first electrodes and a plurality of the second electrodes are electrically connected through the wire.

17. The bonding apparatus as defined by claim 14,
wherein a tip of the wire is formed in a shape of a ball, and is bonded to an electrode by the first tool, and
wherein the wire is held by the second tool and cut in a state to allow the tip of the wire to remain on the electrode.

18. The bonding apparatus as defined by claim 17,
wherein a bump is formed by the tip of the wire remained on the electrode.

19. The bonding apparatus as defined by claim 14,
wherein the wire is cut near an end of the first tool by the second tool without feeding the wire out of the first tool.

20. The bonding apparatus as defined by claim 14,
wherein the wire is cut by raising the first and second tools at the same time.

21. The bonding apparatus as defined by claim 14,
wherein the wire is fed by lowering the second tool.
